(19) United States
(12) Patent Application Publication
(10) Pub. No.: US 2025/0109016 A1
(43) Pub. Date: Apr. 3, 2025

(54) PRODUCTION METHOD FOR A MICROMECHANICAL SENSOR COMPONENT AND CORRESPONDING MICROMECHANICAL SENSOR COMPONENT

(71) Applicant: Robert Bosch GmbH, Stuttgart (DE)

(72) Inventors: Richard Fix, Weil Im Schoenbuch (DE); Susanne Wicker, Reutlingen (DE)

(21) Appl. No.: 18/897,010

(22) Filed: Sep. 26, 2024

(30) Foreign Application Priority Data
Sep. 29, 2023 (DE) 10 2023 209 592.0

(51) Int. Cl. B81C 1/00; B81B 7/00

(52) U.S. Cl. CPC B81C 1/00793; B81B 7/0029; B81B 2201/02; B81B 2203/0127; B81B 2207/11; B81C 2201/0128; B81C 2203/032

(57) ABSTRACT

A production method for a micromechanical sensor component and a corresponding micromechanical sensor component. The production method includes: providing a sensor wafer with a plurality of micromechanical sensor chips, which include one or more relevant sensor regions; forming an access wafer with one or a corresponding plurality of access chips, which in each case include one or more access regions to the sensor regions, which form relevant media access regions for the sensor regions; attaching the access wafer to the sensor wafer, so that the access regions are arranged above the corresponding sensor region(s); and separating the sensor chips with the access chips glued thereon, in order to obtain a plurality of sensor component chips.

### CROSS REFERENCE

The present application claims the benefit under 35 U.S.C. § 119 of German Patent Application No. DE 10 2023 209 592.0 filed on Sep. 29, 2023, which is expressly incorporated herein by reference in its entirety.

### FIELD

The present invention relates to a production method for a micromechanical sensor component and to a corresponding micromechanical sensor component.

### BACKGROUND INFORMATION

Both in literature and in sensor components available on the market, a wide variety of media sensors (gas sensors, humidity sensors, pressure sensors) are already equipped with membranes/porous layers for filtering the ambient media or for preventing contamination or the ingress of liquids. The filter/membrane layers are integrated directly into the sensor housing, for example by gluing the membrane onto or into the housing or by pouring the membrane into the housing mass (molding). Here, the term “media” is used to refer to all substances in the liquid or gaseous state of aggregation.

This is accompanied by the following problems:
a) large area consumption of the filter materials
b) many potential leaks
c) complex production process at the sensor level

PCT Patent Application No. WO 2016 041 727 A2 relates to a field device for process and/or automation technology for monitoring at least one chemical or physical process variable of a medium in an at least partially and temporarily media-carrying component comprising at least one electronics unit and a sensor unit, wherein at least one component of the sensor unit is in contact with the media at least in a subregion and at least temporarily, wherein at least the media-contacting subregion of the component is provided with a media-resistant multilayer coating made up of at least two layers, wherein a first layer consists of a material which is made up of a densely packed atomic arrangement and provides corrosion protection for the medium, wherein arranged around the first layer is a second layer, which consists of a chemically resistant plastic and which offers protection for the first layer against external damage and corrosion.

German Patent Application No. DE 10 2017 118 504 A1 relates to a protection device for a sensor unit of an optochemical sensor for determining and/or monitoring at least one analyte in a medium, comprising at least one protective substance for protecting the sensor unit from a physical and/or chemical change caused by at least one substance contained in the medium, and an at least partially media-permeable functional layer, wherein the protection device can be attached or applied to the sensor unit in a region facing the medium. Furthermore, an optochemical sensor with a protection device is described.

### SUMMARY

The present invention provides a production method for a micromechanical sensor component and a corresponding micromechanical sensor component.

Preferred developments of the present invention are disclosed herein.

An idea underlying the present invention is not to shield a sensor as a whole from certain environmental influences, but to protect particularly sensitive individual chip components (sensor regions) against external environmental influences, e.g., against certain gases or contaminants, or to maintain selectivity toward comparable components.

According to an example embodiment of the present invention, an access region of an access chip, which comprises at least one access region, which preferably only allows defined media to pass through, in at least one subregion, is applied to a sensor chip surface which comprises at least one sensor region. Other chips in the same package remain unaffected.

This access region being applied directly to the sensor chip surface and not being integrated into the packaging/stacking and thus not being applied to the entire sensor component provides the following advantages:
individual sensor elements with one or more sensor regions can be equipped with different access elements and thus fulfill different functionalities or have different sensitivities,
less material consumption,
better and easier sealing of a smaller area,
protection against harmful influences that may occur within the sensor component housing,
simpler production process, possible in large quantities at the wafer level where appropriate.

According to a preferred embodiment of the present invention, the access regions comprise continuous open access regions. These access regions are suitable for pressure sensor regions, for example.

According to a further preferred embodiment of the present invention, the continuous open access regions are formed by completely trenching the access wafer or access substrate or by partially trenching and subsequently backgrinding the access wafer or access substrate.

According to a further preferred embodiment of the present invention, the access region(s) comprise filtered access regions, in and/or on which one or more filter elements are arranged. This keeps disruptive media away from the sensor regions.

According to a further preferred embodiment of the present invention, the filtered access regions are formed by completely trenching the access wafer or access substrate and subsequently introducing and/or applying a filter material.

According to a further preferred embodiment of the present invention, the filtered access regions are formed by partially trenching the access wafer or access substrate and subsequently locally porosifying the untrenched region. This allows cavities to be formed between the sensor regions and the relevant filter element.

According to a further preferred embodiment of the present invention, the filtered access regions are formed by completely locally porosifying the access wafer or access substrate.

According to a further preferred embodiment of the present invention, the filter elements comprise catalytic filter elements with at least one catalytic layer.

According to a further preferred embodiment of the present invention, the filter elements comprise porous filter elements with a plurality of regions of different porosity.

According to a further preferred embodiment of the present invention, the filter elements comprise heatable filter elements.

### BRIEF DESCRIPTION OF THE DRAWINGS

The present invention is explained in more detail below based upon the exemplary embodiments indicated in the schematic figures.

FIG. 1 shows a schematic cross-sectional view for illustrating a micromechanical sensor component and a corresponding production method according to a first example embodiment of the present invention.

FIG. 2 shows a schematic cross-sectional view for illustrating a micromechanical sensor component and a corresponding production method according to a second example embodiment of the present invention.

FIG. 3 shows a schematic cross-sectional view for illustrating a micromechanical sensor component and a corresponding production method according to a third example embodiment of the present invention.

FIG. 4 shows a block diagram for illustrating a production method for a micromechanical sensor component according to a fourth example embodiment of the present invention.

### DETAILED DESCRIPTION OF EXAMPLE EMBODIMENTS

In the figures, identical reference signs denote identical or functionally identical elements.

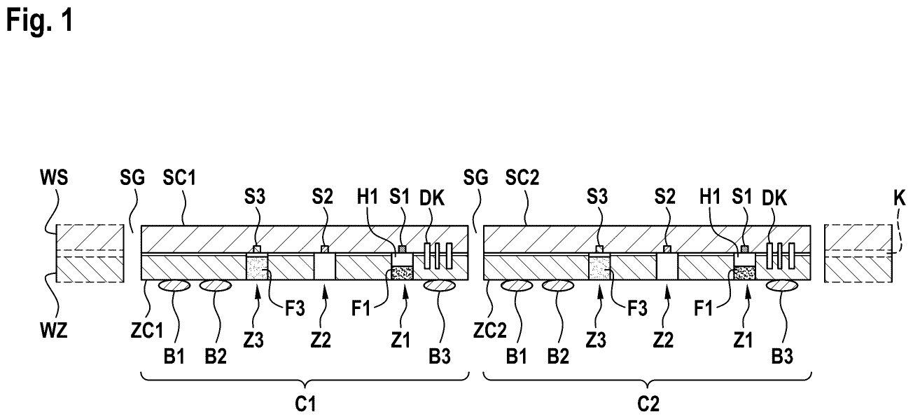

FIG. 1 shows a schematic cross-sectional view for illustrating a micromechanical sensor component and a corresponding production method according to a first embodiment of the present invention.

In FIG. 1, reference sign WS denotes a sensor wafer, e.g., made of silicon, with a plurality of micromechanical sensor chips SC1, SC2, which in each case comprise a first, second and third sensor region S1, S2, S3, for example gas sensor chips for detecting various gases.

Reference sign WZ denotes an access wafer, e.g., likewise made of silicon, with a corresponding plurality of access chips ZC1, ZC2, which comprise a first, second and third access region Z1, Z2, 23, which correspond to the sensor regions S1, S2, S3 and form relevant media access regions (here gases) for the associated sensor region S1, S2, S3.

The access wafer WZ is attached to the sensor wafer WS by means of an adhesive K, e.g., adhesive film or dispensable adhesive, so that the access regions Z1, 22, 23 are arranged in a sealed manner above the corresponding sensor regions S1, S2, S3. The adhesive K leaves out the sensor regions S1, S2, S3, so that the sensor regions S1, S2, S3 are accessible through the access regions Z1, Z2, 23 for the gases to be detected.

The sensor chips SC1, SC2 with the access chips ZC1, ZC2 glued thereon form a plurality of sensor component chips C1, C2, which are separated by saw trenches SG and of which only two sensor component chips C1, C2 are shown in FIG. 1 for the sake of simplicity of illustration.

In order to achieve the best possible seal, the sensor chip SC1, SC2 with the sensor regions S1, S2, S3 should comprise as flat a glueable surface as possible and the adhesive K should be able to tightly seal any steps of a plurality of nanometers in height.

The distance between the relevant sensor region S1, S3, S3—and the associated access region Z1, Z2, 23 can be influenced by a chip, an expandable adhesive film, a chip elevation, another holder or combinations thereof, in order to prevent membrane deflection or direct covering of or contact with the sensor region S1, S2, S3, if necessary.

The access chips ZC1, ZC2 in each case contain an evaluation circuit (not shown), which is electrically connected to the sensor regions S1, S2, S3 via through-connections DK in the access chip ZC1, ZC2 and sensor chip SC1, SC2. The evaluation circuit can in turn be electrically connected to a carrier substrate (not shown) via solder bumps B1, B2, B3.

As an alternative to direct electrical connection via through-connections DK between the access chip ZC1, ZC2 and the sensor chip SC1, SC2, the sensor chip SC1, SC2 can be electrically connected to a carrier substrate by means of bond pads and bond wires and the access chip ZC1, ZC2 can be electrically connected by means of the solder bumps B1, B2, B3.

The first access region Z1 comprises a filter element F1, which only partially fills the first access region Z1 on the side remote from the first sensor region S1. A cavity H1 is located between the first sensor region S1 and the first filter element F1.

The second access region Z2 is open throughout.

The third access region Z3 comprises a filter element F3, which completely fills the third access region.

As filter element F1, F3, various partially-porous materials with one or more layers and different materials are possible, e.g., porous silicon or PTFE with a possible additional functional layer/filter with a smaller pore size.

For example, the sensor regions S1, S3 for gases can be protected with a relevant suitable filter element F1, F3 with pore sizes smaller than the molecular diameter of the gases to be shielded, e.g., certain siloxanes from harmful siloxane sources from outside and inside the sensor housing.

For this purpose, a somewhat more porous element can, for example, be used as a carrier material and a fine-porous element, as a filter element applied thereon, as a base. For example, porous silicon is used in order to achieve a defined pore size, which is applied to a further layer.

A catalytic layer, such as an activated carbon filter, can also be used as a filter element F1, F3, in order to filter out volatile hydrocarbons (VOCS).

Furthermore, heatable access elements with corresponding electrical connections in the sensor chip SC1, Sc2 or access chip ZC1, ZC1 are also possible, e.g., short-term heating for catalytic activity (pre-filtering to convert, for example reducing, in particular hydrocarbon-containing, gases, so that they no longer reach the sensor region S1, S3 or are converted into a gas that is easier to detect) and/or for an accumulated measurement (in order to accumulate gases that occur in low concentrations, over a longer period of time and then to apply them in a high concentration abruptly to the sensor by means of heating).

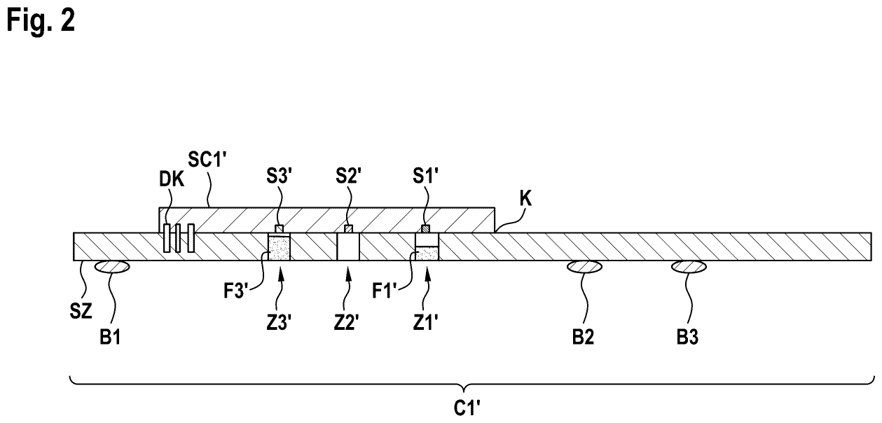

FIG. 2 shows a schematic cross-sectional view for illustrating a micromechanical sensor component and a corresponding production method according to a second embodiment of the present invention.

In the second embodiment, assembly does not take place at the wafer level, but at the substrate/chip level.

A micromechanical sensor chip SC1′, which comprises a plurality of relevant sensor regions S1′, S2′, S3′, and an access substrate SZ, e.g., an LGA substrate, which comprises access regions Z1′, Z2′, 23′ which correspond to the sensor regions S1′, S2′, S3′ and form relevant media access regions for the sensor regions S1, S2′, S3′, are provided for this purpose.

The access substrate SZ is glued to the sensor chip SC1′, so that the access regions Z1′, Z2′, Z3′ are arranged above the corresponding sensor regions S1, S2′, S3′.

The filter elements F1′, F2′, F3′ correspond to the filter elements F1, F2, F3, which were already explained above.

Otherwise, the second embodiment is constructed analogously to the first embodiment.

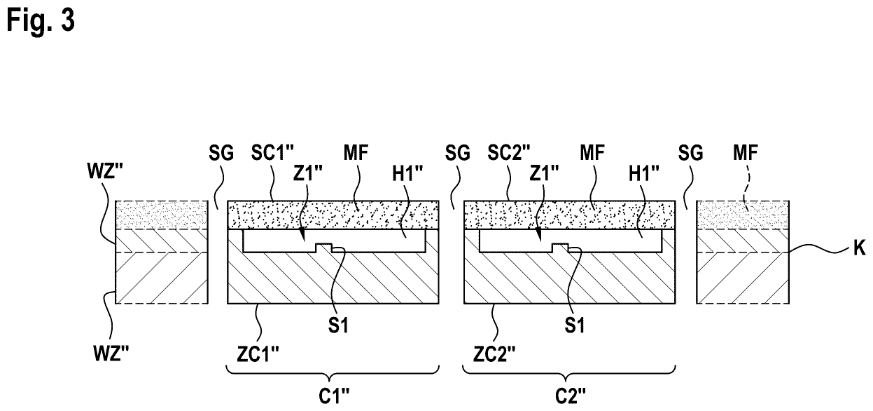

FIG. 3 shows a schematic cross-sectional view for illustrating a micromechanical sensor component and a corresponding production method according to a third embodiment of the present invention.

In the third embodiment, the access wafer WZ″ is glued to the sensor wafer WS″ and a filter film MF, as a filter element, is glued to the side thereof remote from the sensor wafer WS″.

The sensor chips SC1″, SC2″ with the access chips zC1″, ZC2″ glued thereon form a plurality of sensor component chips C1″, C2″, which are separated by saw trenches SG and of which only two sensor component chips C1, C2 are shown in FIG. 3 for the sake of simplicity of illustration.

The micromechanical sensor chips SC1″, SC2″ in each case comprise a first sensor region S1, for example gas sensor chips for detecting a gas.

The access chips ZC1″, ZC2″ comprise a first access region Z1″, which corresponds to the sensor region S1 and forms a media access region (here gas) for the associated sensor region S1. The access region Z1″ is spanned by the filter film MF, as a filter element, and comprises a cavity H1″ between the filter film MF and the sensor region S1. The filter film MF, possibly deflectable filter film, thus has a defined distance to the sensor region S1 in order to avoid mechanical contact therewith.

Otherwise, the second embodiment is constructed analogously to the first embodiment.

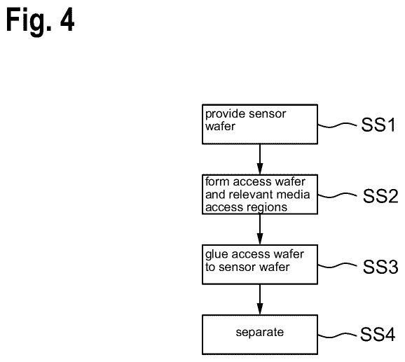

FIG. 4 shows a block diagram for illustrating a production method for a micromechanical sensor component according to a fourth embodiment of the present invention.

With reference to FIG. 1, the production method comprises the following steps SS1 to SS4.
In step SS1, a sensor wafer WS with a plurality of micromechanical sensor chips SC1, SC2, which comprise one or more relevant sensor regions S1, S2, S3, is provided.
In step SS2, an access wafer WZ is formed with a corresponding plurality of access chips ZC1, ZC2, which comprise access regions Z1, Z2, Z3, which correspond to the sensor regions (S1, S2, S3) and form relevant media access regions for the sensor regions S1, S2, S3.
In step SS3, the access wafer WZ is glued to the sensor wafer WS, so that the access regions Z1, 22, 23 are arranged above the corresponding sensor regions S1, S2, S3.

In step SS4, the sensor chips SC1, SC2 with the access chips ZC1, ZC2 glued thereon are separated in order to obtain a plurality of sensor component chips C1, C2.

Further optional steps include, for example, backthinning the sensor wafer WS and/or the access wafer WZ and applying additional protective layers or pressure membrane layers to certain access regions or gelling certain access regions, under which pressure sensor regions are located, for example.

Although the present invention has been completely described above with reference to preferred exemplary embodiments, it is not limited thereto, but can be modified in many ways.

In particular, the materials and structures specified are indicated only by way of example and not in a limiting manner.

What is claimed is:

1. A production method for a micromechanical sensor component, comprising the following steps:
providing a sensor wafer with a plurality of micromechanical sensor chips, which each include one or more relevant sensor regions;
forming an access wafer with one or a corresponding plurality of access chips, which in each case include one or more access regions to the sensor regions, which form relevant media access regions for the sensor regions;
attaching the access wafer to the sensor wafer, so that the access regions are arranged above the corresponding ones of the sensor regions; and
separating the sensor chips with the access chips attached thereon, to obtain a plurality of sensor component chips.

2. A production method for a micromechanical sensor component, comprising the following steps:
providing a micromechanical sensor chip, includes one or more sensor regions;
forming an access substrate with a plurality of the sensor regions, which in each case include one or more access regions to the sensor regions, which form relevant media access regions for the sensor regions;
attaching the sensor chip to the access substrate, so that the access regions are arranged above corresponding ones of the sensor regions.

3. The production method according to claim 1, wherein the access regions include continuous open access regions.

4. The production method according to claim 3, wherein the continuous open access regions are formed by completely trenching the access wafer or by partially trenching and subsequently backgrinding the access wafer.

5. The production method according to claim 1, wherein the access regions include filtered access regions in and/or on which one or more filter elements are arranged.

6. The production method according to claim 5, wherein the filtered access regions are formed by completely trenching the access wafer and subsequently introducing and/or applying a filter material.

7. The production method according to claim 5, wherein the filtered access regions are formed by partially trenching the access wafer and subsequently locally porosifying the untrenched region.

8. The production method according to claim 5, wherein the filtered access regions are formed by completely locally porosifying the access wafer.

9. The production method according to claim 5 wherein the filter elements include catalytic filter elements with at least one catalytic layer.

10. The production method according to claim 5, wherein the filter elements include porous filter elements with a plurality of regions of different porosity.

11. The production method according to claim 5, wherein the filter elements include heatable filter elements.

12. A micromechanical sensor component, comprising:
a micromechanical sensor chip, which includes one or more relevant sensor regions;
an access chip or an access substrate, which includes one or more access regions to the sensor regions, which form relevant media access regions for the sensor regions;
wherein the access chip or the access substrate is attached to the sensor chip, so that the access regions are arranged above corresponding ones of the sensor regions.

13. The micromechanical sensor component according to claim 12, wherein the access regions: (i) include continuous open access regions and/or (ii) include filtered access regions in and/or on which one or more filter elements are arranged.

14. The micromechanical sensor component according to claim 12, wherein the access regions include catalytic filter elements with at least one catalytic layer.

15. The micromechanical sensor component according to claim 12, wherein the access regions include porous filter elements with a plurality of regions of different porosity.

16. The micromechanical sensor component according to claim 12, wherein the access regions include filtered access regions in and/or on which one or more filter elements are arranged, and wherein the filter elements include heatable filter elements.
